(19) United States
(12) Patent Application Publication
(10) Pub. No.: US 2025/0107027 A1
(43) Pub. Date: Mar. 27, 2025

(54) EXTENSION RING

(71) Applicant: Hubbell Incorporated, Shelton, CT (US)

(72) Inventors: Stephen Michael Boener, Goshen, IN (US); Jonathan Randall Falls, Gilbert, AZ (US); Krishna C. Patel, Granger, IN (US)

(73) Assignee: Hubbell Incorporated, Shelton, CT (US)

(21) Appl. No.: 18/891,480

(22) Filed: Sep. 20, 2024

Related U.S. Application Data
(60) Provisional application No. 63/584,703, filed on Sep. 22, 2023.

(51) Int. Cl. H05K 5/03; H05K 5/02

(52) U.S. Cl. CPC H05K 5/03; H05K 5/0217; H05K 5/0247

(57) ABSTRACT

An in-use cover for an electrical device includes a base having an internal volume and a lid pivotably connected to the base. The base includes an upper cavity, and an extension ring coupled to the upper cavity. The upper cavity and the extension ring are integrally formed from a unitary piece. The lid is movable between an open position that at least partially exposes the electrical device and a closed position that can enclose the electrical device in the internal volume.

### CROSS-REFERENCE TO RELATED APPLICATION

This application claims the benefit of U.S. Provisional Application No. 63/584,703, filed Sep. 22, 2023, the entire contents of which is incorporated herein by reference in its entirety.

### FIELD

The present disclosure relates to a cover. More particularly, the present disclosure relates to an integrally formed while-in-use cover that accommodates different sized plugs.

### BACKGROUND

While-in-use covers may be used to cover and/or protect electrical devices, like electrical outlets. Particularly, while-in-use covers may be used with outdoor electrical receptacles to help limit liquid (e.g., precipitation, condensation, etc.) from reaching the electrical device (e.g., and damaging the circuitry).

While-in-use covers may be used with extension rings to provide a volume for housing an electrical device. For example, various codes and/or standards may require specific volumes for use with different electrical devices. An extension ring may provide additional spacing between an electrical device housed in an electrical box and the while-in-use cover.

The extension ring may be separate from the while-in-use cover and may be assembled between the cover and the electrical box as needed. This assembly method requires additional sealing to ensure that there are no inadvertent ingresses for liquid to reach the electrical device.

### SUMMARY

Various examples of the present disclosure can overcome various of the aforementioned and other disadvantages and offer new advantages as well.

According to one aspect of various examples of the present disclosure there is provided an in-use cover that is formed as a unitary piece.

According to one aspect of various examples of the present disclosure there is provided an in-use cover for housing a cord and an electrical device. A retaining member extends from an inner surface of a lid toward a portion of the cord. The retaining member is dimensioned so that the cord cannot be disconnected from the electrical device while the lid is closed.

According to one aspect of various examples of the present disclosure there is provided an in-use cover for housing a cord and an electrical device. A spacer is disposed within an internal volume of the in-use cover and is coupled to the electrical device. The spacer is dimensioned so that the cord cannot be disconnected from the electrical device while a lid is closed.

According to one aspect of various examples of the present disclosure there is provided an in-use cover for housing a cord and an electrical device. An adjustable mud ring is disposed within an internal volume of the in-use cover and is coupled to the electrical device. The adjustable mud ring is dimensioned so that the cord cannot be disconnected from the electrical device while a lid is closed.

According to one aspect of various examples of the present disclosure there is provided an in-use cover for housing a cord and an electrical device. The in-use cover is dimensioned so that the cord cannot be disconnected from the electrical device while a lid is closed.

According to one aspect of various examples of the present disclosure there is provided an in-use cover that has a body with an upper section that can receive an electrical device and an electrical cord. The body also has an extension ring integrally formed with the upper section that can provide additional space for receiving the electrical device.

According to one aspect of various examples of the present disclosure there is provided an electrical enclosure that includes an upper section, an electrical box, and an extension ring disposed between the upper section and the electrical box. The extension ring can provide additional clearance for an electrical device housed in the electrical enclosure. The extension ring and the upper section can be integrally formed from a unitary piece of material.

According to another aspect of various examples of the present disclosure, there is provided an in-use cover for an electrical device. The cover includes a base having an internal volume and a lid pivotably connected to the base. The base includes an upper cavity, and an extension ring coupled to the upper cavity. The upper cavity and the extension ring are integrally formed from a unitary piece. The lid is movable between an open position that at least partially exposes the electrical device and a closed position that can enclose the electrical device in the internal volume.

According to another aspect of various examples of the present disclosure, there is provided electrical enclosure for housing an electrical device. The electrical enclosure includes an in-use cover, a lid, and an electrical box. The cover includes a base having an internal volume. The base includes an upper cavity, an extension ring coupled to the upper cavity, and a flange disposed between within the internal volume between the upper cavity and the extension ring. The upper cavity and the extension ring are integrally formed from a unitary piece. The lid is pivotably connected to the base. The lid is movable between an open position that at least partially exposes the internal volume and a closed position that is configured to enclose the internal volume. The electrical box coupled to the extension ring and configured to expand the internal volume.

According to another aspect of various examples of the present disclosure, there is provided an in-use cover that includes a base having an internal volume, a lid pivotably connected to the base, and electrical box, and an electrical device. The base includes an upper cavity, an extension ring coupled to the upper cavity, and a flange disposed between within the internal volume between the upper cavity and the extension ring. The upper cavity and the extension ring are integrally formed from a unitary piece. The lid is movable between an open position that at least partially exposes the internal volume and a closed position that is configured to enclose the internal volume. The electrical box is coupled to the extension ring and configured to expand the internal volume. The electrical device is coupled to the flange and accessible within the upper cavity. The electrical device extends toward the electrical box. The extension ring provides clearance between the electrical device and a surface of the electrical box.

According to another aspect of various examples of the present disclosure, there is provided an in-use cover that includes a base having an internal volume and a flange disposed between within the internal volume. The in-use cover also includes a lid is movable between an open position that at least partially exposes the internal volume and a closed position that is configured to enclose the internal volume. The electrical device is coupled to the flange and accessible within the upper cavity. The electrical device extends toward the electrical box. An electrical cord is removably coupled to the electrical device. The in-use cover is dimensioned so that the cord cannot be disconnected from the electrical device while a lid is closed.

The disclosure herein should become evident to a person of ordinary skill in the art given the following enabling description and drawings. The drawings are for illustration purposes only and are not drawn to scale unless otherwise indicated. The drawings are not intended to limit the scope of the disclosure. The following enabling disclosure is directed to one of ordinary skill in the art and presupposes that those aspects within the ability of the ordinarily skilled artisan are understood and appreciated.

### BRIEF DESCRIPTION OF THE DRAWINGS

Various aspects and advantageous features of the present disclosure will become more apparent to those of ordinary skill when described in the detailed description of preferred examples and reference to the accompanying drawing wherein:

FIG. 1 is a perspective view of a cover with an integrally formed extension for use in housing an electrical device.

FIG. 2 is a side view of the cover of FIG. 1.

FIG. 3 is a rear view of the cover of FIG. 1.

FIG. 4 is a front view of the cover of FIG. 1.

FIG. 5 is a perspective view of the cover of FIG. 1 with a lid pivoted to an open position.

FIG. 6 is a side view of the cover of FIG. 5.

FIG. 7 is a cross-sectional view of cover of FIG. 1 viewed along section 7-7.

FIG. 8 is a cross-sectional view of the cover of FIG. 5, viewed along section 8-8.

FIG. 9 is a cross-sectional view of the cover of FIG. 1, viewed along section 9-9.

FIG. 10 is a perspective view of the cover of FIG. 1 connected to an electrical box.

FIG. 11 is a side view of the cover and box of FIG. 10.

FIG. 12 is a front view of the cover and box of FIG. 10.

FIG. 13 is a rear view of the cover and box of FIG. 10.

FIG. 14 is a perspective view of the cover and box of FIG. 10 illustrating a lid pivoted to an open position and including a first electrical connector.

FIG. 15 is an exploded view of the cover and box of FIG. 10.

FIG. 16 is a cross-sectional view of the cover and box of FIG. 14, viewed along section 16-16.

FIG. 17 is a top view of the box and cover of FIG. 10, illustrating the first electrical connector with the lid removed.

FIG. 18 is a perspective view of the cover and box of FIG. 10, illustrating the lid pivoted to an open position and the cover including a faceplate for supporting a second electrical connector.

FIG. 19 is an exploded view of the cover and box of FIG. 18.

FIG. 20 is a cross-sectional view of the cover and box of FIG. 18, viewed along section 20-20.

FIG. 21 is a top view of the box and cover of FIG. 10, illustrating the first electrical connector with the lid removed.

FIG. 22 is a perspective view of the cover and box of FIG. 10 receiving an electrical connector.

FIG. 23 is a perspective view of the cover and box of FIG. 22, with the lid pivoted to the open position.

FIG. 24 is a cross-sectional view of the cover and box of FIG. 23, viewed along section 24-24.

FIG. 25 is a cross-sectional view of the cover and box of FIG. 22, viewed along section 25-25.

FIG. 26 is a perspective view of an alternate example of a cover connected to an electrical box.

FIG. 27 is a cross-sectional view of the cover and box of FIG. 26 viewed along line 27-27 illustrating a first retaining member.

FIG. 28 is a cross-sectional view of the cover and box of FIG. 26, illustrating the first retaining member and a lid pivoted to an open position.

FIG. 29 is a cross-sectional exploded view of the cover of FIG. 26, illustrating the first retaining member and the lid.

FIG. 30 is a cross-sectional view of the cover and box of FIG. 26 viewed along line 27-27 illustrating a second retaining member.

FIG. 31 is a cross-sectional view of the cover and box of FIG. 26, illustrating the second retaining member and a lid pivoted to an open position.

FIG. 32 is a cross-sectional exploded view of the cover of FIG. 26, illustrating the second retaining member and the lid.

FIG. 33 is a cross-sectional view of the cover and box of FIG. 26 viewed along line 27-27 illustrating an adjustable stop.

FIG. 34 is a cross-sectional view of the cover and box of FIG. 26 viewed along line 34-34 illustrating the adjustable stop.

FIG. 35 is a perspective view of the adjustable stop.

FIG. 36 is a perspective view of multiple adjustable stops of FIG. 35 connected together.

FIG. 37 is a cross-sectional view of the cover and box of FIG. 26 viewed along line 27-27 illustrating an adjustable mud ring.

FIG. 38 is a cross-sectional view of the cover and box of FIG. 26, illustrating the adjustable mud ring and a lid pivoted to an open position.

FIG. 39 is a perspective view the adjustable mud ring of FIG. 37.

FIG. 40 is a perspective view of another example of a cover with an integrally formed extension for use in housing an electrical device.

FIG. 41 is a front view of the cover of FIG. 40.

FIG. 42 is a cross-sectional view of the cover of FIG. 40, viewed along section 42-42.

FIG. 43 is a perspective view of the cover of FIG. 40, illustrating a lid pivoted to an open position.

FIG. 44 is an exploded view of the cover of FIG. 40.

### DETAILED DESCRIPTION

The present disclosure is related to a while-in-use cover that may be used with a variety of electrical devices. The while-in-use cover may be used to house outdoor electrical devices to protect the devices from various forms of weather. The while-in-use cover may also be used with indoor electrical devices.

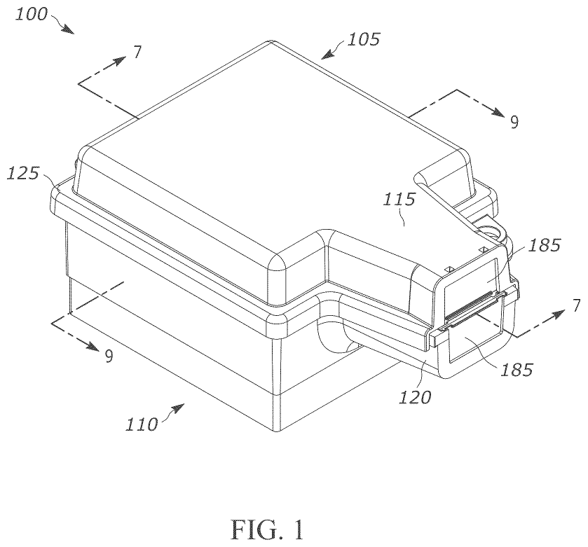

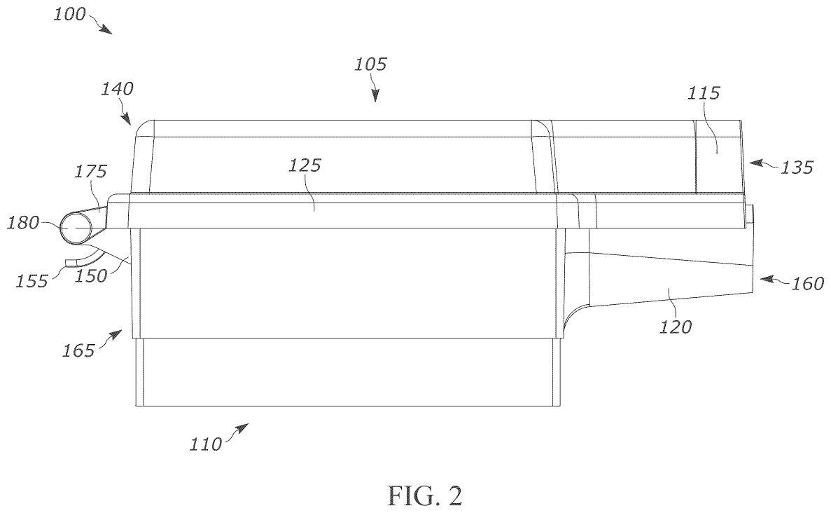

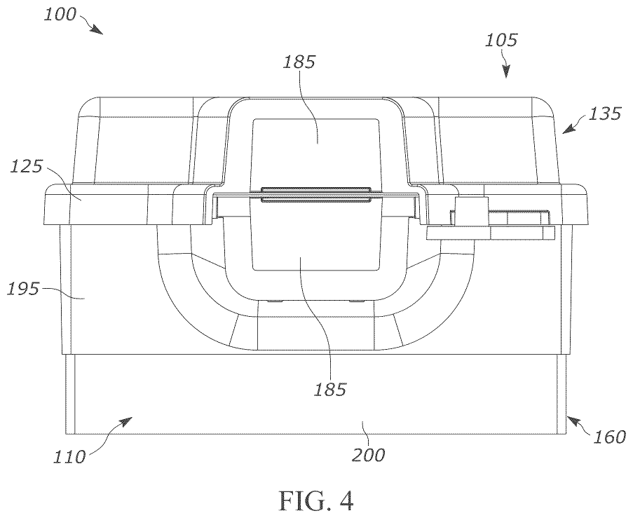

As shown in FIGS. 1 to 9, a while-in-use cover 100 may include a lid 105 coupled to a base 110. The lid 105 and the base 110 may have a substantially complementary shape, which may permit the lid 105 to interface with the base 110. In the illustrated example, the lid 105 and the base 110 may have a substantially rectangular shape, although the lid 105 and/or the base 110 may also include a different shape.

In certain forms, the lid 105 may include a neck 115 and the base 110 may include a complementary neck 120. Each neck 115, 120 may extend away from the generally rectangular shape. Each illustrated neck 115, 120 may have a tapered shape (e.g., with a free end being narrower). However, in other examples, the necks 115, 120 may include a constant width.

As shown in FIGS. 1, 2, and 9, the lid 105 may include a lip 125 that extends at least partially around a perimeter of the lid 105. For example, the illustrated lip 125 may extend continuously around the perimeter of the lid 105, although in other examples, there may be one or more discontinuities in the lip 125.

As shown in FIG. 9, the base 110 may include a flange 130 at an upper end. The flange 130 may have a complementary shape to the lip 125 and may be sized and shaped to permit the lip 125 to engage the flange 130. The illustrated example of the flange 130 may be substantially rectangular in shape and may extend outwardly from an outer surface of the base 110.

The lip 125 may have a greater width than a width of the base 110. This may permit the lid 105 to fit over the flange 130 of the base 110 and couple the lid 105 and the base 110 to one another. For example, the lip 125 may be sized to permit the lid 105 to selectively engage the flange 130 of the base 110 with a snap fit, although other types of connections may be used (e.g., a press fit, a friction fit, a magnetic connection, an adhesive, fasteners (e.g., threaded screws), swing arms etc.).

Returning to FIGS. 1 to 4, the lid 105 may include a first end 135 and a second end 140 opposite to the first end 135. The neck 115 may extend to the first end 135. As will be described in more detail below, the neck 115 may be hollow and may include an opening 145 at the first end 135.

The second end 140 may include a first hinge portion 150 that may assist in connecting the lid 105 to the base 110. In the illustrated example, the first hinge portion 150 may include a pair of discrete elements spaced apart from one another (although other examples may include any number of elements). Each element of the first hinge portion 150 may be substantially cylindrical in shape and may include a hollow center.

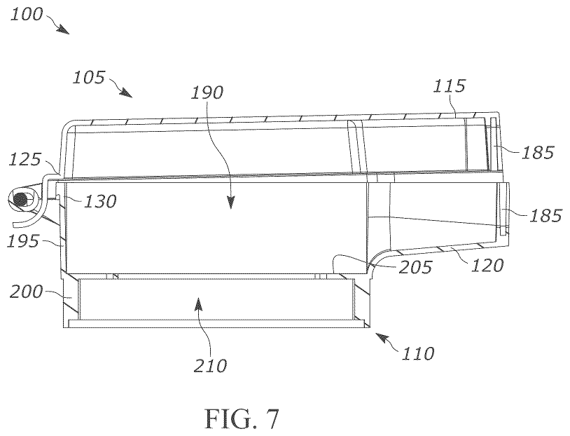

A guide 155 may also be disposed on the second end 140. In the illustrated example, the guide 155 may be positioned between the elements of the first hinge portion 150, although in other examples, the guide 155 may have any other position. The guide 155 include a curved surface (see e.g., FIG. 7).

The base 110 may similarly include a first end 160 and a second end 165. The neck 120 may extend to the first end 160. As will be described in more detail below, the neck 120 may be hollow and may include an opening 170 at the first end 160.

The second end 165 may include a second hinge portion 175 that may assist in connecting the lid 105 to the base 110. In the illustrated example, the second hinge portion 175 may include a hollow element disposed substantially in a center of the base 110. The second hinge portion 175 may be substantially cylindrical in shape and may include a hollow center that is substantially the same size as the hollow centers of the first hinge portion 150.

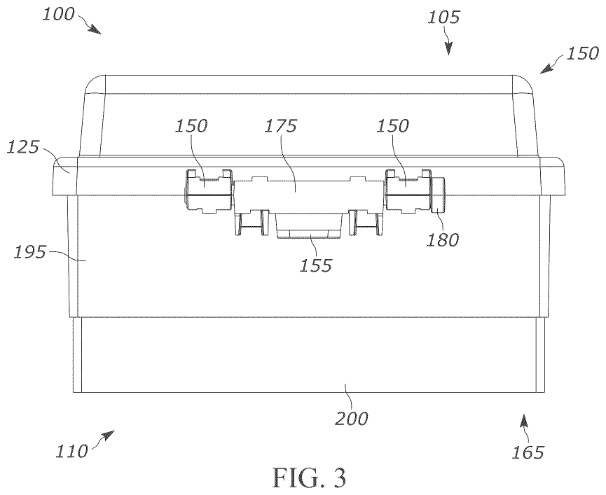

As shown in FIG. 3, the lid 105 may be connected to the base 110 by positioning the elements of the first hinge portion 150 on either side of the second hinge portion 175. As the lid 105 is fitted onto the base 110, the lip 125 of the lid 105 may contact the flange 130 of the base 110. In this position, the lip 125 and flange 130 may engage to form a seal between the lid 105 and the base 110. Additionally, the flange 130 may support the lid 105 so that the first hinge portion 150 is aligned with the second hinge portion 175. In other words, the hollow center of the elements of the first hinge portion are aligned with the hollow center of the second hinge portion 175. A pin 180 may be inserted through the hollow centers to connect the first and second hinge portions 150, 175 together. The pin 180 permits the lid 105 to pivot relative to the base 110.

In some forms, a biasing member (e.g., a spring-not shown) may be connected to the pin 180. The biasing member may bias the lid 105 toward the closed position. The biasing member may provide a spring force sufficient to create an auto-latch feature. For example, the biasing member may pull the lid 105 toward the base 110 with enough force so that the snap fit engages when the lid 105 is released. This may assist in ensuring that the cover 100 remains closed when a user does not need to access the internal volume 190, which limits liquid ingress.

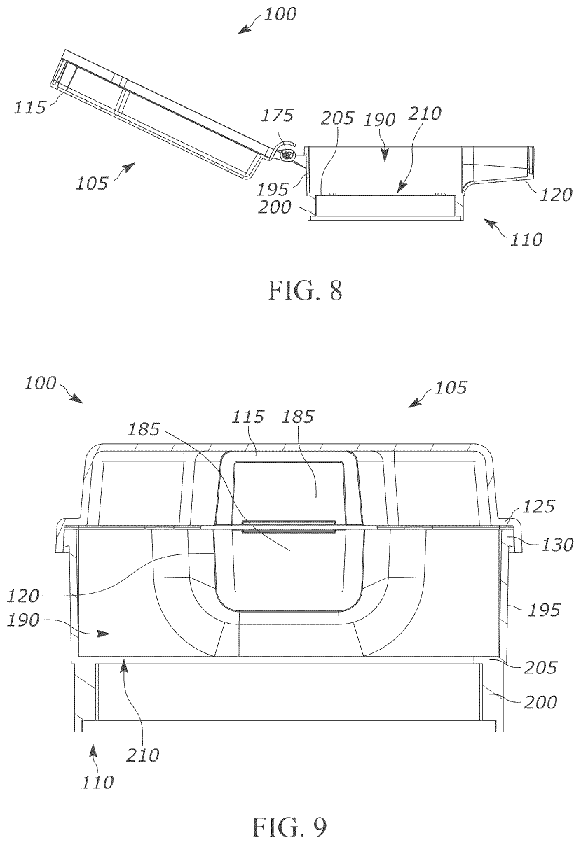

As illustrated in FIGS. 7 and 8, the curved surface of the guide 155 can move about the second hinge portion 175 without contacting the second hinge portion 175 of the base 110. The guide 155 may limit translational movement between the lid 105 and the base 110 while the pin 180 is connected to the first and second hinge portions 150, 175.

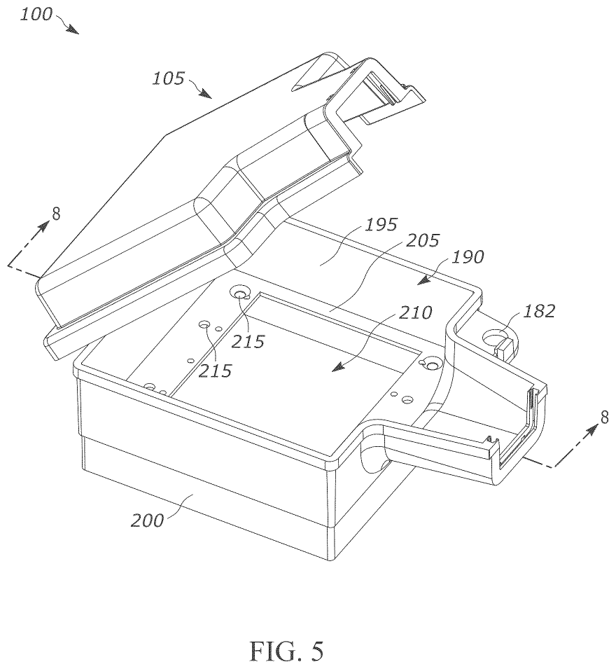

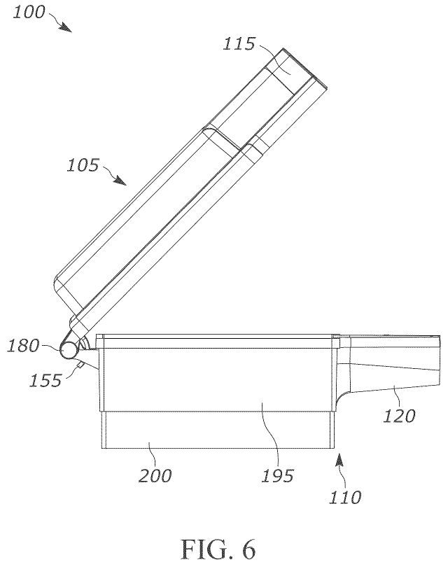

The lid 105 is selectively movable between a closed position (see e.g., FIGS. 1 to 4) and an open position (see e.g., FIGS. 5 and 6). In the closed position, the lid 105 may be secured to the base 110 and may limit the ingress of fluids into a volume of the cover 110. A snap-fit (or other similar connection) may selectively secure the lid 105 to the base 110 and limit the lid 105 from pivoting relative to the base. The lid 105 may also include a first locking aperture 181 that may align with a second locking aperture 182 of the base 110 when the lid 105 is in the closed position. A padlock (or other locking mechanism—not shown) may connect to the cover 100 through the first and second locking apertures 181, 182. This may limit unauthorized movement of the lid 105 relative to the base 110.

One or more blocking portions 185 may be positioned in the necks 115, 120 to further prevent the ingress of fluids. For example, a single blocking portion 185 may extend across both necks 115, 120 or an individual blocking portion 185 may be positioned in each neck 115, 120. The blocking portion(s) 185 may be constructed from a liquid-resistant material (e.g., a gel) and may substantially seal the necks 115, 120. As described in more detail below, the blocking portion(s) 185 may be repositionable and/or removable to permit an electrical device to extend into the volume of the cover 100.

As shown in FIG. 5, the base 110 may include an internal volume 190 that may be at least partially enclosed by the lid 105 (e.g., in the closed position of FIG. 1). The base 110 include an upper cavity 195 and an extension ring 200 that extends from the upper cavity 195. Both the upper cavity 195 and the extension ring 200 may be at least partially hollow to form the internal volume 190.

In some forms, the upper cavity 195 and the extension ring 200 may be integrally formed with one another. For example, the upper cavity 195 and the extension ring 200 may be formed during a single manufacturing process (e.g., molding), and may be a single, unitary piece. A common wall may extend between the upper cavity 195 and the extension ring 200 so that there is no gap or other possible ingress along the interface between the upper cavity 195 and the extension ring 200. The base 110 may further not require sealing between the upper cavity 195 and the extension ring 200 because they are formed as a single, unitary piece.

In certain forms, the upper cavity 195 and the extension ring 200 may be at least partially constructed from a resilient material (e.g., silicone). For example, a transition between the upper cavity 195 and the extension ring 200 may be formed from the resilient material, which may permit the upper cavity 195 to move relative to the extension ring 200 without the upper cavity 195 disconnecting from the extension ring 200. For example, a transition between the upper cavity 195 and the extension ring 200 may be formed by one or more telescopic members that may be expandable or collapsible to change the volume of the cover 100 depending on a size of an electrical device and/or a mounting space. A similar expandable cover is disclosed in U.S. Pat. No. 7,541,540, which is incorporated herein by reference in its entirety.

In some forms, the upper cavity 195 may have a larger width than the extension ring 200. As shown in FIG. 6, the base 110 may include a stepped transition between the upper cavity 195 and the extension ring 200. As described above, a unitary wall may extend across the transition between the upper cavity 195 and the extension ring 200.

As shown in FIGS. 7 to 9, a lower end of the extension ring 200 may include a rim 202 that extends away from the upper cavity 195. The rim 202 may be formed at an outer perimeter of the extension ring 200 and may include a stepped surface at least partially within the interior volume 190.

With continuing reference to FIGS. 7 to 9, a flange 205 may be formed across a portion of the internal volume 190. For example, the flange 205 may extend from the transition between the upper cavity 195 and the extension ring 200. The flange 205 may leave a central opening 210 that allows passage between the upper cavity 195 and the extension ring 200 across the internal volume 190.

Returning to FIG. 5, the flange 205 may not be symmetrical along its entire perimeter. For example, the flange 205 may be wider proximate to the first end 160 and the second end 165 and may be thinner along edges of the base 110 that extend between the first and second ends 160, 165.

In certain forms, the wider portions of the flange 205 may include one or more apertures 215, which may be formed in a variety of shapes and sizes. As described in more detail below, one or more electrical devices may be secured to the flange 205 within the internal volume using one or more of the apertures 215.

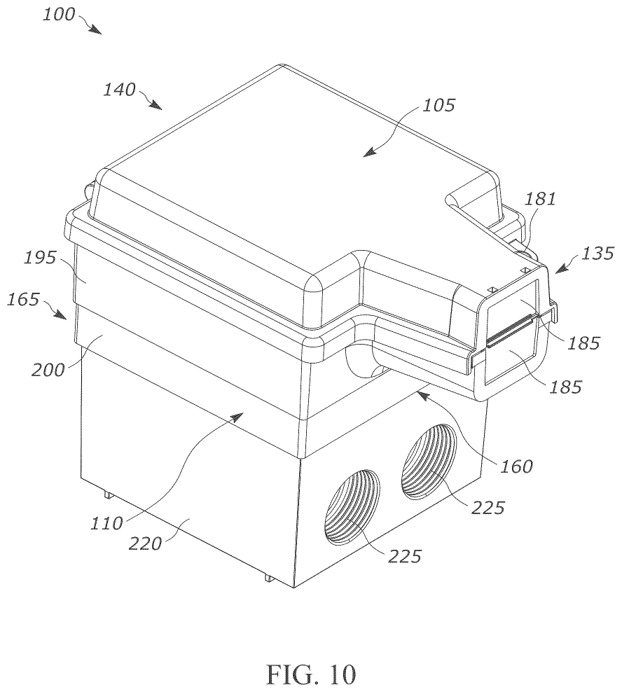

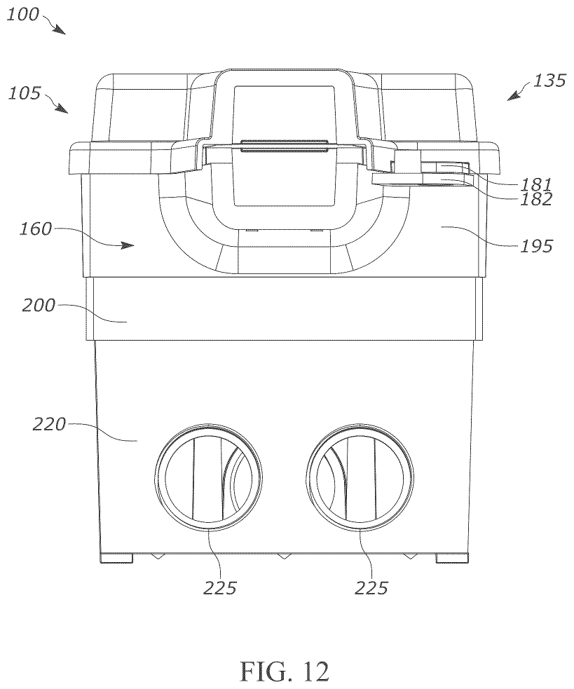

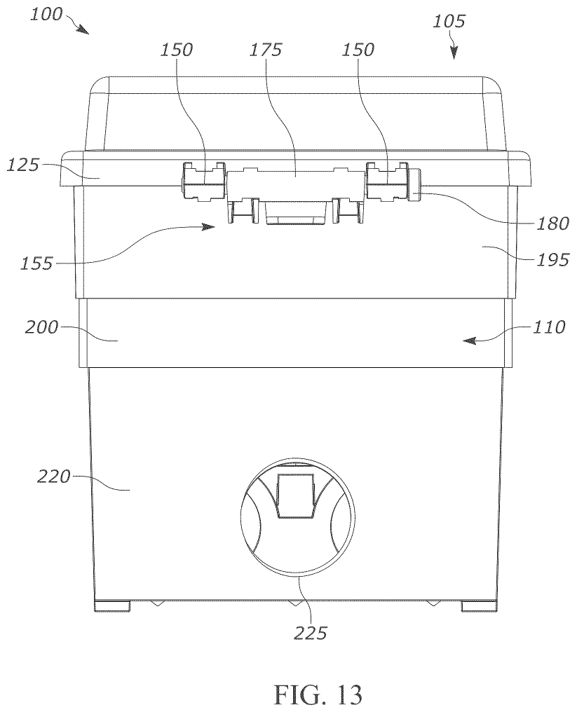

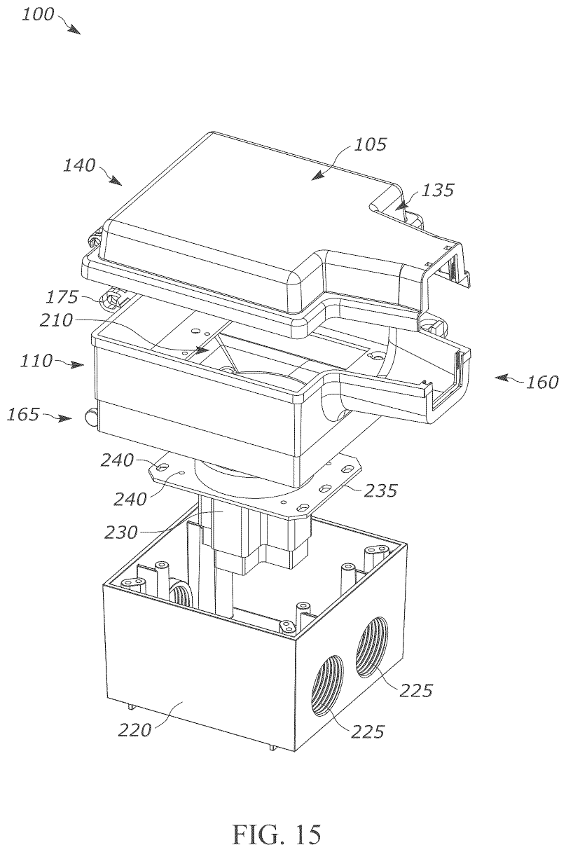

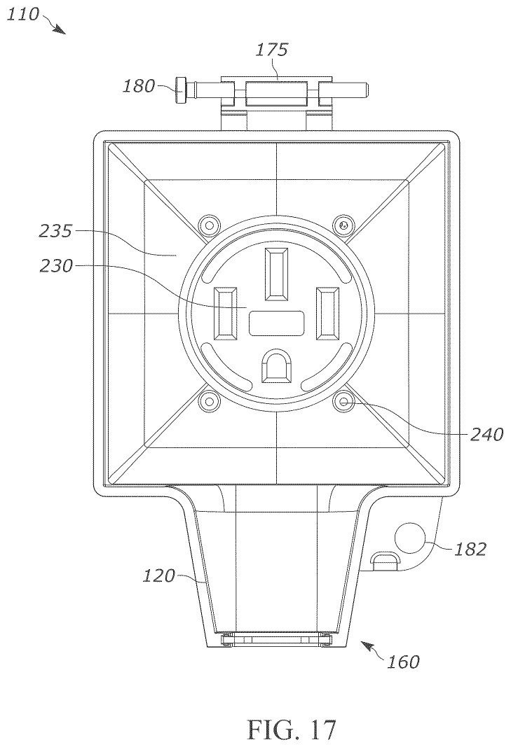

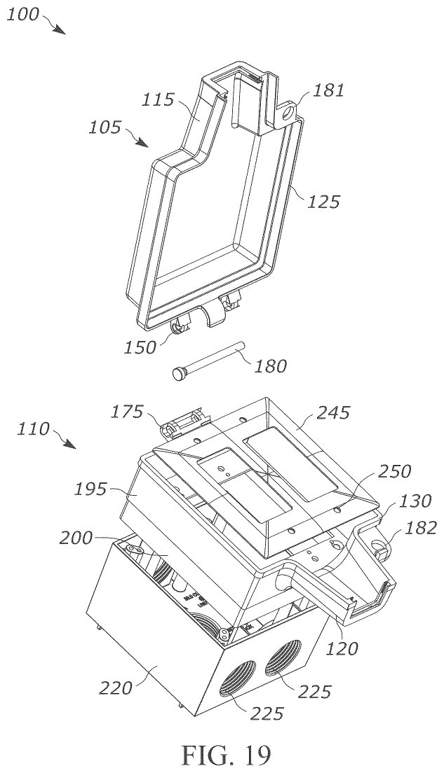

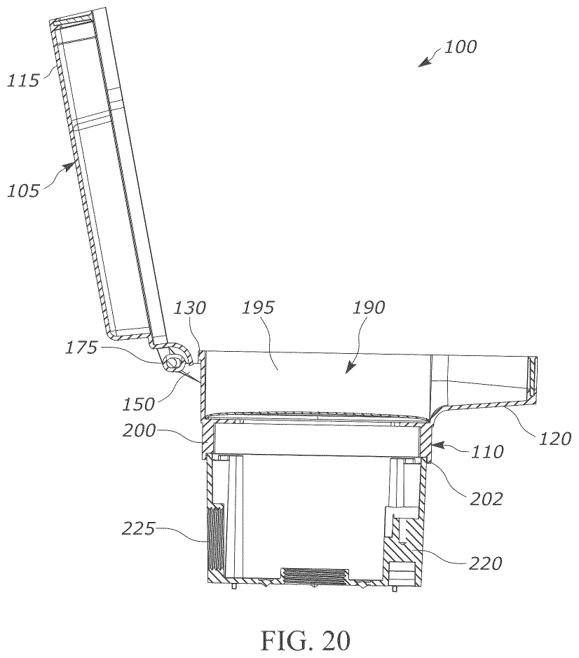

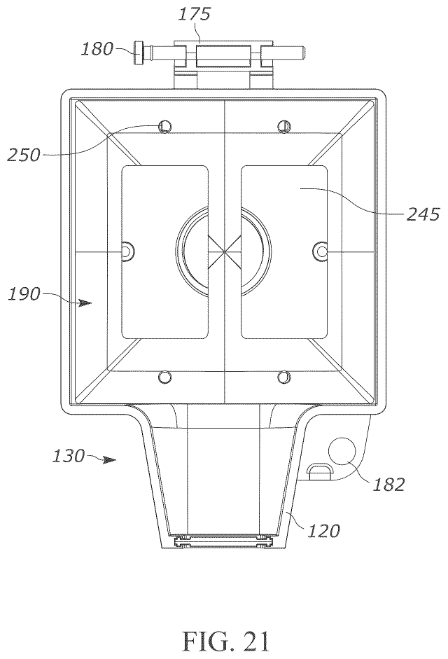

As shown in FIGS. 10 to 24, the cover 100 may be connected to an electrical box 220. For example, the electrical box 220 may connect to the extension ring 200 to expand and enclose the internal volume 190. The rim 202 of the extension ring 200 may engage an edge of the electrical box 220 (e.g., with a snap fit, a press fit, a friction fit, etc.). Additional fasteners (e.g., threaded screws) or swing arms may also be used to form a connection between the electrical box 220 and the cover 100.

A gasket (not shown) may be disposed between the cover 100 and the electrical box 220 to form a seal when the rim 202 of the extension ring 200 engages an edge of the electrical box 220. In other examples, a sealing compound may be used instead of or in addition to the gasket. Once connected, the engagement between the electrical box 220 and the cover 100 may form a substantially water-resistant engagement (e.g., to limit ingress of liquids into the internal volume 190). The illustrated electrical box 220 may have a substantially rectangular profile, although other examples may include other shapes.

In other examples, the cover 100 and the electrical box 220 may be formed as a single, unitary piece. As described above, forming elements as a unitary piece may limit fluid paths where leaks can occur.

In some forms, walls of the electrical box 220 may include apertures 225. The illustrated apertures 225 may be substantially circular in shape and may be threaded, although the apertures 225 may be any size or shape.

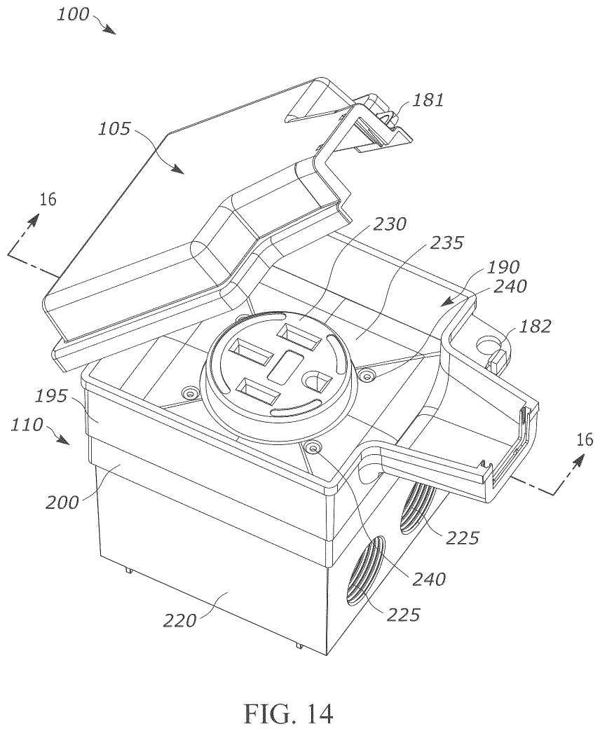

As shown in FIGS. 14 to 17, a first electrical device 230 may be positioned within the internal volume 190. The illustrated first electrical device 230 may be a 14-50 electrical outlet, to which a charging cord for an electric vehicle may be connected.

In some forms, a plate 235 may be connected to the first electrical device 230. The plate 235 may be a substantially planar element with a substantially rectangular shape. The plate 235 may also include one or more fastening holes 240. In certain forms, the plate 235 may be integrally formed with the first electrical device 230 so that the plate 235 and the first electrical device 230 are permanently connected. In other examples, the plate 235 may be separable from the first electrical device 230.

The plate 235 may have a shape substantially the same as the flange 205 disposed between the upper cavity 195 and the extension ring 200. Additionally, the first electrical device 230 may have an outer width that is less than the width of the central opening 210. When connecting the electrical device to the cover 100, the plate 235 may rest on an upper surface of the flange 205 (e.g., with the upper cavity 195) and the first electrical device 230 may be accessible within the upper cavity 195 and may extend through the central opening and into the electrical box 220.

In some forms, the plate 230 is connected to the flange 205 using one or more fasteners (not shown). When the plate 230 rests on the flange 205, the fastening holes 240 of the plate 235 may be aligned with the apertures 215 of the flange 205. A fastener may be inserted through an aligned aperture 215 and fastening hole 240 to secure the plate to the flange 205.

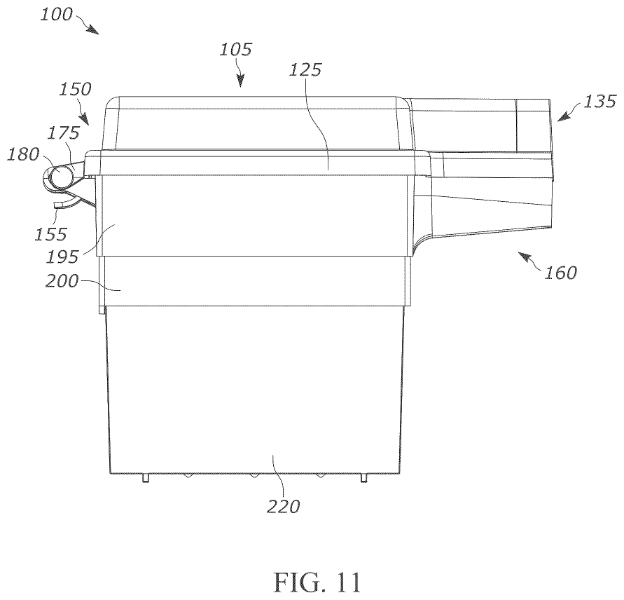

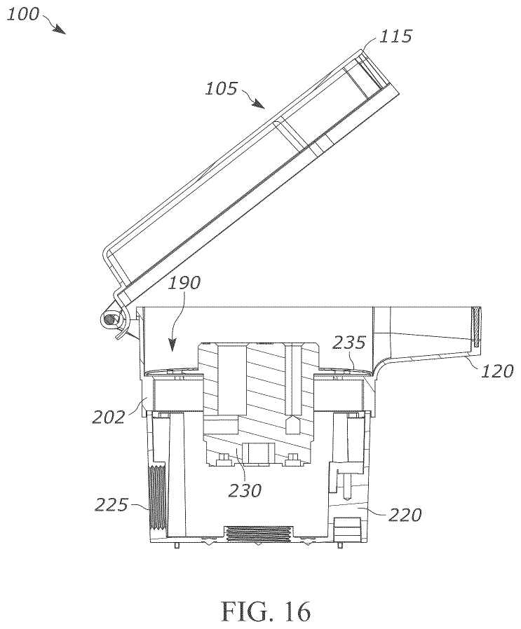

In the assembled position (see e.g., FIG. 16), the first electrical device 230 is positioned within the internal volume 190. To be appropriately situated, the first electrical device 230 should be spaced apart from the lid 105 and from the bottom of the electrical box 220. This helps to ensure that the lid 105 can pivot to a fully closed position (see e.g., FIG. 11) and electrical conductors (not shown) can connect to a lower end of the first electrical device 230 (e.g., through the apertures 225). The extension ring 200 may assist in increasing the internal volume and providing a greater distance between the lid 105 and the electrical box 220, thus providing more space to receive the first electrical device 220.

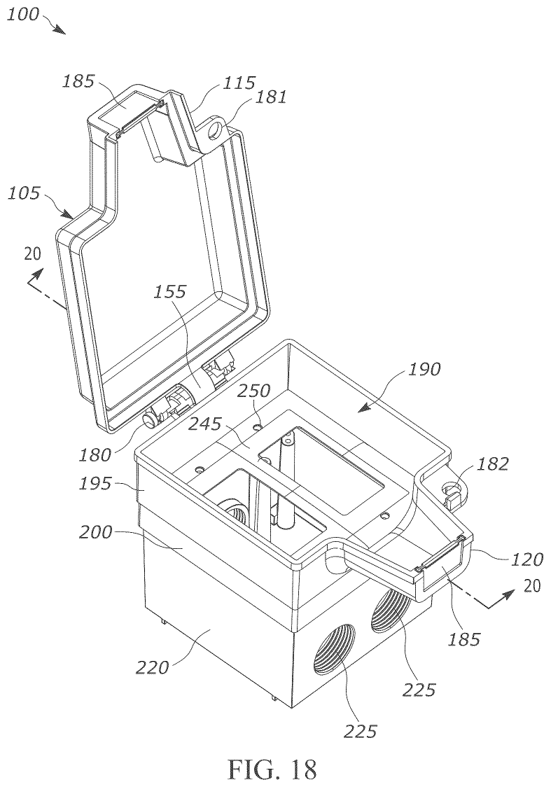

As shown in FIGS. 18 to 21, the cover 100 may be used with a second electrical device (not shown). For example, the second electrical device may be a standard electrical outlet, a GFCI outlet, a USB outlet, etc. In the illustrated example, the plate 235 supporting the first electrical device 230 may be replaced with a faceplate 245. The illustrated faceplate 245 is a two-gang faceplate 245 and may support two electrical devices. Other examples of the faceplate 245 may be a single-gang faceplate that supports one second electrical device.

In some forms, the faceplate 245 may be substantially rectangular in shape and may include an outer dimension that is like the outer dimension of the flange 205. The faceplate 245 may include at least one fastener opening 250 disposed proximate to an outer perimeter of the faceplate 245. When positioned within the internal volume 190, the fastener openings 250 may be aligned with the apertures 215. A fastener (not shown) may be inserted through an aligned fastener opening 250 and aperture 215 to secure the faceplate within the cover 100.

A second electrical device may be received through the faceplate 245 so that it is accessible within the upper cavity 195 (e.g., the plug of an electrical outlet faces into the upper cavity 195). The second electrical device may also extend toward the electrical box 220 where it can connect to an electrical conductor. The second electrical device may be smaller than the first electrical device, but the extension ring 200 may still provide additional clearance between the second electrical device and the electrical box 220.

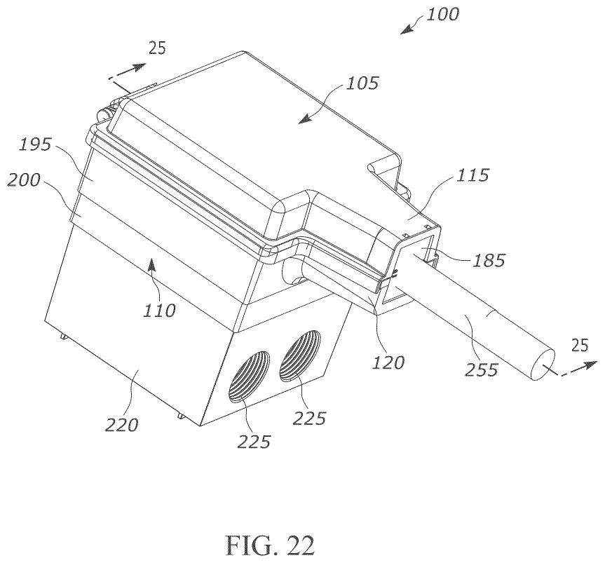

As shown in FIGS. 22 to 25, a power cord 255 may be connected to an electrical device housed in the cover 100. The illustrated power cord 255 may be an EV changing cord that can removably connect to the first electrical device 230, although other types of electrical cords may be used (e.g., when the second electrical device is received within the cover 100).

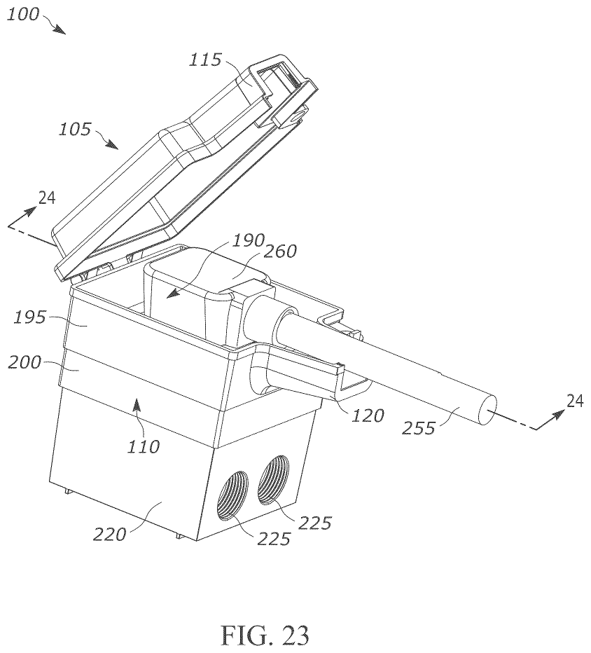

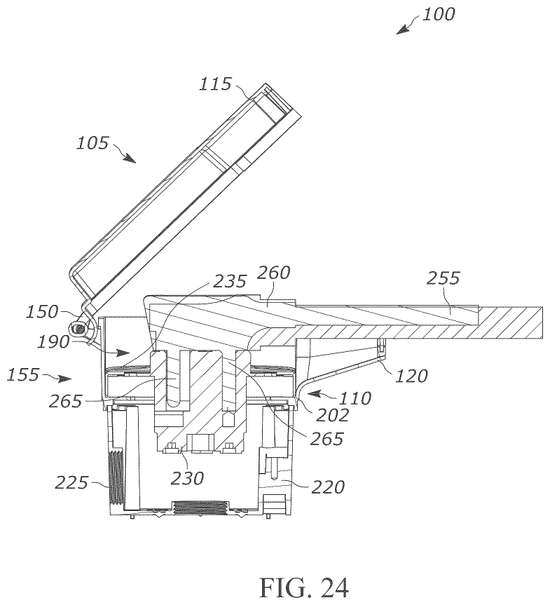

As shown in FIGS. 23 and 24, the power cord 255 may include a head 260 from which electrical contacts 265 extend. The power cord 255 may be a right angle plug where the electrical contacts 265 extend in a direction substantially perpendicular from the direction of the cable of the power cord 255.

In use, the lid 105 may be at least partially decoupled from the base 110 so that the lid 105 can pivot relative to the base 110 and expose the first electrical device 230 housing within the cover 100. The electrical contacts 265 of the power cord 255 can be inserted into openings of the first electrical device 230 to establish an electrical connection. The power cord 255 may be oriented so that it extends out of the cover 100 through the neck 120.

In some forms, the blocking portion 185 may be positioned within the neck 120. The power cord 255 may contact the blocking portion 185 and cause it to deform. For example, the weight of the power cord 255 may compress the blocking portion 185 to permit the power cord 255 to be at least partially seated within the neck 185. The blocking portion 185 may experience elastic deformation and attempt to return to its initial portion. The blocking portion 185 may be constructed from a material such that when it attempts to expand, it creates a seal around the surface of the power cord 255.

Once the power cord 255 is positioned within the base 110, the lid 105 may be pivoted to the closed position. The neck 115 may enclose a portion of the power cord 255 and may at least partially limit the movement of the power cord 255. For example, a width of a passage formed by the necks 115, 120 may be similar to a width of the power cord 255. When the lid 105 is closed and secured (e.g., via a snap fit), the end of the power cord 255 proximate to the head 260 may be supported by the necks 115, 120 and limited from moving.

In some forms, the neck 115 may include a blocking portion 185 that may deform as the lid 105 pivots toward the closed position and comes into contact with the power cord 255. After deforming, the blocking portion 185 may attempt to return to its original position and may create a seal around a portion of the power cord 255. Additionally, the blocking portions 185 in each neck 115, 120 may contact one another to form a seal. The blocking members 185 may therefore substantially limit liquid from reaching the first electrical device 230.

In other forms, there may be different sized blocking portions 185, which may be selected and positioned within the necks 115, 120 based on the diameter of the power cord 255. For example, smaller blocking members 185 may be utilized when a larger power cord 255 (e.g., one associated with EV charging) is used.

In other forms, material from the blocking portions 185 may be removed to accommodate the diameter of the power cord 255. For example, the blocking portions 185 may include perforations that correspond to different diameters. A user may remove a section of the blocking portions 185 along the perforations. Alternatively, a user may cut the blocking portions 185 to remove desired section of material (e.g., if perforations are not included).

In still other forms, the blocking portions 185 may be eliminated. To reduce the likelihood that liquid enters the internal volume, the cover 100 may be oriented so that the necks 115, 120 are facing the ground. Liquid therefore may need to oppose gravity to reach the electrical device. Alternatively, when used in an indoor environment, the cover 100 may be oriented with the necks 115, 120 at any orientation when the blocking portions 185 are not present as the likelihood of liquid entering the internal volume 190 is reduced.

When the lid 105 is in the closed position (e.g., snap fit to the base 110), a lock may be inserted through the locking apertures 181, 182 to selectively secure the lid 105 to the base 110. This may limit tampering with the power cord 255 and/or unauthorizing pivoting of the lid 105 relative to the base 110.

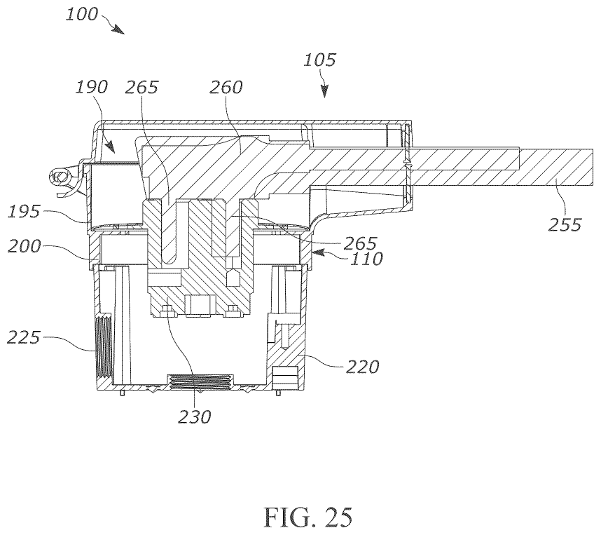

As shown in FIG. 25, the cover 100 may be structured to limit the clearance of the head 260 within the internal cavity 190. When the lid 105 is closed, there may be only a small gap between the top surface of the head 260 and the inner surface of the lid 105. This distance may be insufficient permit the head 260 to move relative to the first electrical device 230. For example, if a person attempted to disconnect the head 260 from the first electrical device 230, the head 260 would come into contact with the lid 105 before the electrical contacts 265 where fully removed from the first electrical device 230. In other words, while the lid 105 is in the closed position, the lid 105 prevents the electrical contacts 265 from breaking electrical contact with the first electrical device 230. This may assist in limiting tampering with a supply of electrical power (e.g., purposefully stopping an electrical vehicle from charging).

In other examples where the faceplate 245 and the second electrical devices are used instead of the first electrical device, the lid and size of the internal volume 190 may similarly limit tampering with the connection between the second electrical devices and the cords. For example, the plugs on the cords used with the second electrical devices may be received within the internal volume and may be prevented from electrically disconnecting from the second electrical device when the lid 105 is secured to the base 110 because there is an insufficient amount of space to move the plugs.

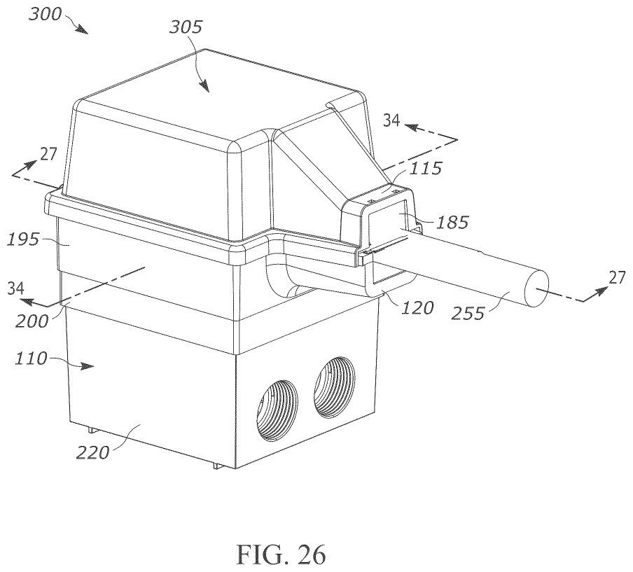

FIG. 26 shows an alternate example of a cover 300 that is connected to an electrical box 220. The cover 300 may be similar to the cover 100 described above. However, the lid 305 of the cover 300 may be larger than the lid 105, which may permit a larger internal volume 190. One or more additional features may be provided to limit unauthorized or unintentional removal of the head 260 of the power cord 255 while the lid 305 is in the closed position.

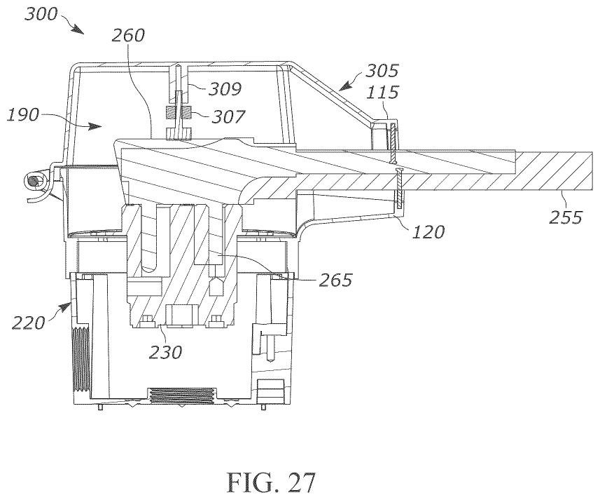

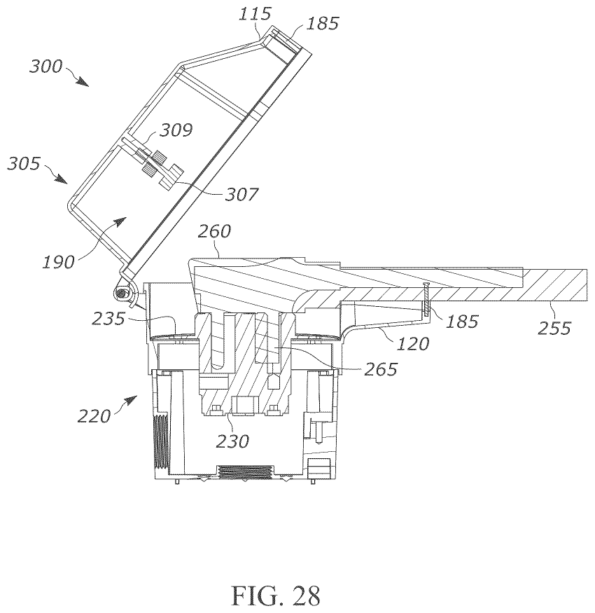

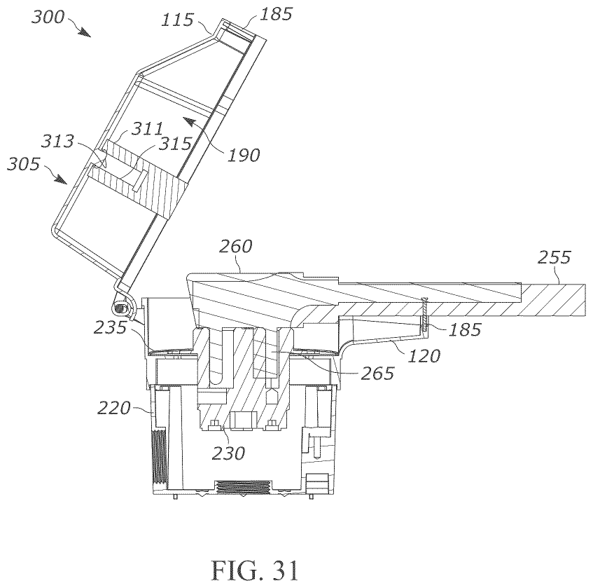

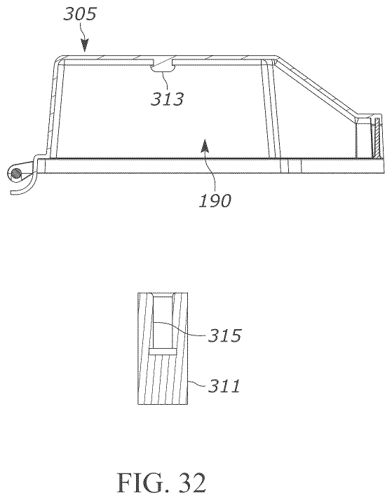

FIGS. 27 to 32 illustrate two examples of a first blocking feature designed to limit the unintentional or unauthorized removal of the head 260 while the lid 305 is in the closed position. As described in more detail below, these first blocking features may provide a physical barrier to limiting the removal of the head 260 for the electrically connected position when the lid 305 is closed.

As shown in FIGS. 27 to 29, the cover 300 may include a first retaining member 307. The illustrated first retaining member 307 may be a jack screw, although any type of retaining member may be used.

The lid 305 may include a channel 309 that extends from an internal surface. The width of the channel 309 may be sized and shaped to at least partially receive the first retaining member 307. For example, the first retaining member 307 may be inserted into the channel 309. In some forms, the first retaining member 307 may be secured within the channel 309 using a friction fit, a press fit, an adhesive, or any other similar retention means. In other examples, the first retaining member 307 may include a channel that can receive a projection that extends from the surface of the lid 305.

In some forms, the first retaining member 307 may be adjustable. Specifically, the distance that the first retaining member 307 extends from the channel 309 can be selectively adjusted. For example, a jack screw can be rotated so that its total length is selectively adjusted.

When using a cover 300 with a larger internal volume, the distance between the head 260 of the power cord 255 and the inner surface of the lid 305 may be large enough that the head 260 can be unplugged while the lid 305 remains closed. This could permit an unauthorized user to disconnect the head 260. The first retaining member 307 may be positioned proximate or adjacent to the head 260, and thereby reduce the free space between the head 260 and the lid 305. In other words, the first retaining member 307 may act as a stop to limit the inadvertent or unauthorized disconnection of the head 260 while the lid 305 is in the closed position. The length of the first retaining member 307 may therefore be adjusted based on the distance between the head 260 and the lid 307 to help ensure that the space between the head 260 and the first retaining member 307 to substantially too small to permit the disconnection of the head 260.

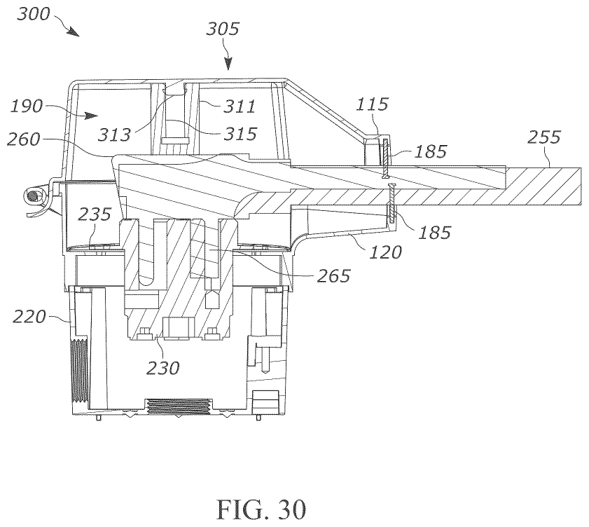

As shown in FIGS. 30 to 32, the cover 300 may include a second retaining member 311. The illustrated first retaining member 307 may be a stop, although any type of retaining member may be used.

The lid 305 may include a projection 313 that extends from an inner surface of the lid 305. The illustrated projection 313 may be substantially dome-shaped, although the projection 313 may include any other shape.

In some forms, the second retaining member 311 may have a substantially cylindrical shape. However, other shapes may be used without departing from the scope of the example. For example, the second retaining member 311 may have a rectangular shape.

In some forms, the second retaining member 311 may include a channel 315 formed as an inner diameter. The channel 315 may extend at least partially through a body of the second retaining member 311 and may be configured to receive the projection 313. For example, the projection 313 may connect to the channel 315 with a friction fit, a press fit, and/or a snap fit. Also, or in addition, an adhesive, a magnet, or any other form of connection may be used to secure the second retaining member 311 to the lid 305. In other examples (not shown), the projection 313 may be replaced with a channel that may receive a portion of the second retaining member 311.

The second retaining member 311 may be similar to the first retaining member 307. In particular, the second retaining member 311 may be sized and shaped to be positioned in close proximity to or in contact with the head 260 of the power cord 255. The distance between the end of the second retaining member 311 and the head 260 may be smaller than the height of the head 260 and electrical contacts 265 to limit inadvertent or unauthorized removal of the head 260 while the lid 305 is in the closed position.

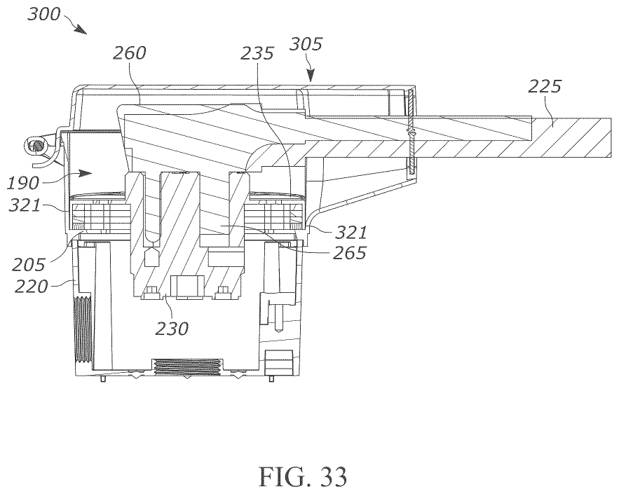

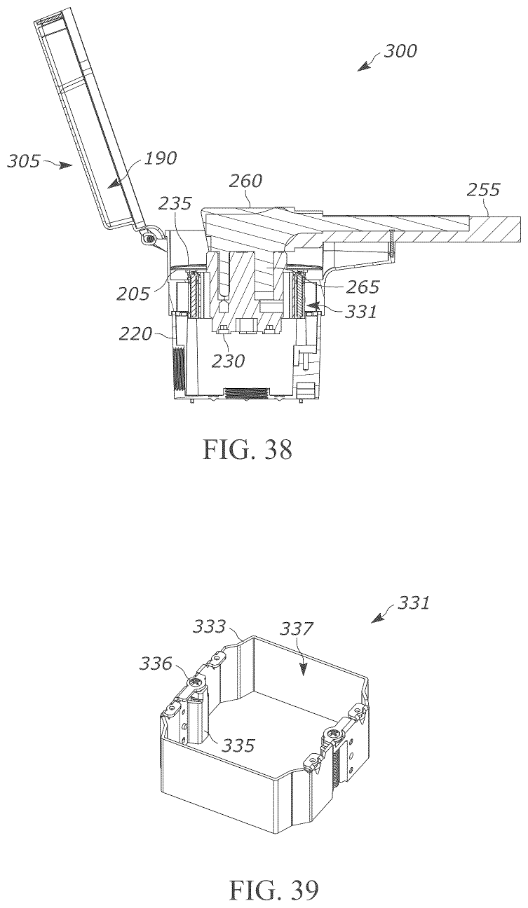

FIGS. 33 to 39 illustrate two examples of a second blocking feature designed to limit the unintentional or unauthorized removal of the head 260 while the lid 305 is in the closed position. As described in more detail below, these second blocking features may raise the upper surface of the head 260 closer to the surface of the lid 305 to limit the freedom of movement for the head 260 when the lid 305 is closed.

As shown in FIGS. 33 to 36, one or more spacers 321 may be positioned within the cover 300. As described in more detail below, the spacers 321 may raise the upper surface of the head 260 closer to the lid 305, which limits the space for the head 260 to move relative to the lid 305.

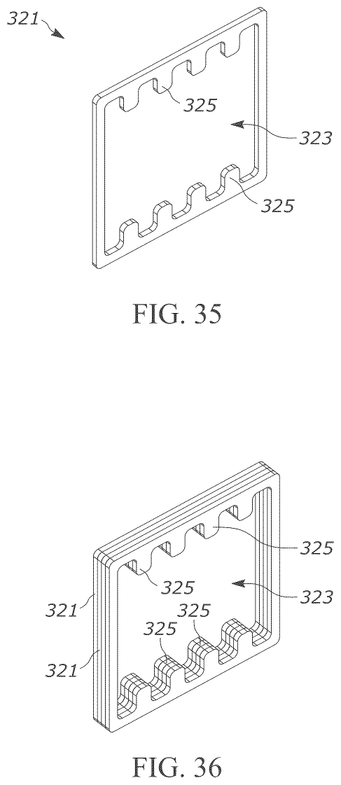

As shown in FIG. 35, the spacer 321 may have a substantially rectangular outer shape, however other examples of the spacer 321 may have a different outer shape (e.g., circular, elliptical, triangular, etc.).

In some forms, the spacer 321 may have an opening 323 disposed radially within the outer perimeter. The illustrated opening 323 may have a substantially rectangular shape, although other shapes (e.g., circular, elliptical, triangular, etc.) may be used.

In certain forms, one or more projections 325 may extend from the perimeter of the opening 323 toward a center of the opening 323. The illustrated spacer 321 may include projections 325 on opposing edges of the opening 323 formed in a substantially saw-tooth shape. The shape and position of the projections 325 may correspond to an outer shape of the first electrical device 230. In other examples, the shape of the opening 323 and/or the projections 325 may be changed to correspond to a differently shaped first electrical device 230.

As shown in FIG. 36, multiple spacers 321 may be coupled together. Each spacer 321 may have a thickness and connecting multiple spacers 321 together may create an increased thickness. The illustrated example shows four equally sized spacers 321 coupled together. However, other examples may include a different number of spacers 321 and/or one or more spacers 321 having a different (i.e., greater or lesser) thickness.

In some forms, the spacers 321 may be coupled to one another using a mechanical fastener (e.g., a bolt or a screw-not shown). In some forms, the spacers 321 may be connected to one another using magnets. In some forms, the spacers 321 may be connected to one another using adhesive. In some forms, one or more of these methods, or any similar method of connection, may be used to couple the spacers 321 together. In still other examples, the spacers 321 may contact one another but may not be connected together.

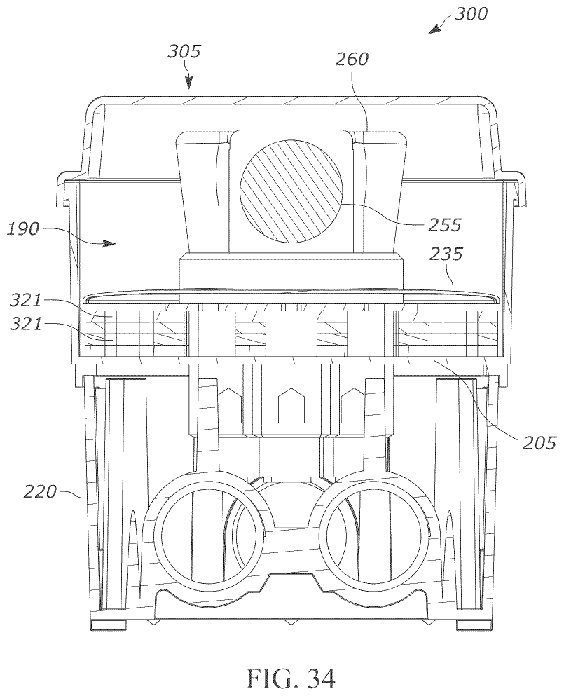

Returning to FIGS. 33 and 34, the spacers 321 may be positioned against the flange 205. The faceplate 235 may be positioned above the spacers 321 so that the spacers 321 are sandwiched between the flange 205 and the faceplate 235. Additionally, the first electrical device 230 may be received through the opening 323 of each spacer 321. In some forms, a fastener (e.g., a bolt or a screw), or another securing means (e.g., an adhesive, press fit, snap fit, or a magnet) may be used to secure the spacers 321 between the faceplate 235 and the flange 205.

Because the first electrical device 230 is supported by the faceplate 235, raising the faceplate 235 via the spacers 321 may raise the head 260 toward the lid 305. By decreasing the distance between the head 260 and the lid 305, the spacers 321 may limit movement of the head 260 while the lid 305 is in the closed position. The number of spacers 321 may be selected based on the size of the first electrical device 230, the size of the head 260, and/or the depth of the lid 305 so that the distance between the head 260 and the lid 305 is less than the length of the electrical contacts 265.

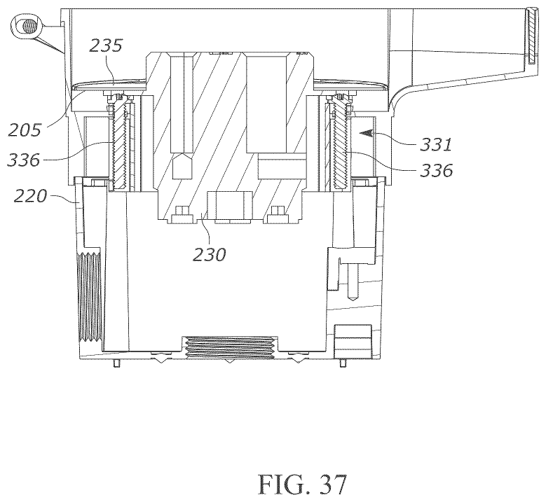

As shown in FIGS. 37 to 39, an adjustable mud ring 331 may be positioned within the cover 300. As described in more detail below, the adjustable mud ring 331 may raise the upper surface of the head 260 closer to the lid 305, which limits the space for the head 260 to move relative to the lid 305.

As shown in FIG. 39, the adjustable mud ring 331 may include a first portion 333, a second portion 335, and a fastener 336 (e.g., a threaded screw). The first and second portions 333, 335 may be movable relative to one another. For example, a user may move (e.g., rotate) the fastener 336 to permit relative movement. A similar adjustable mud ring is disclosed in U.S. Pat. No. 11,025,043, which is incorporated herein by reference in its entirety.

The adjustable mud ring 331 may be disposed within the cover 300 between the flange 205 and the faceplate 235. The adjustable mud ring 331 may also include a central opening 337 that may receive the first electrical device 230. A user may adjust the relative position of the first and second portions 333, 335 to change the height of the first electrical device 230 within the cover 330. This may permit the user to reduce the distance between the head 260 and the cover 305 to limit inadvertent and/or unauthorized removal of the head 260 when the lid 305 is closed.

In some forms, one or more first blocking features may be used with one or more second blocking features. For example, the first and/or second retaining member 307, 311 may be used with the spacers 321 and/or the mud ring 331. For example, the spacers 321 and/or the mud ring 331 may raise the first electrical device 230 to be closer to the lid 305. The first and/or second retaining member 307, 311 may extend from the lid 305 to be positioned proximate or adjacent to the head 260.

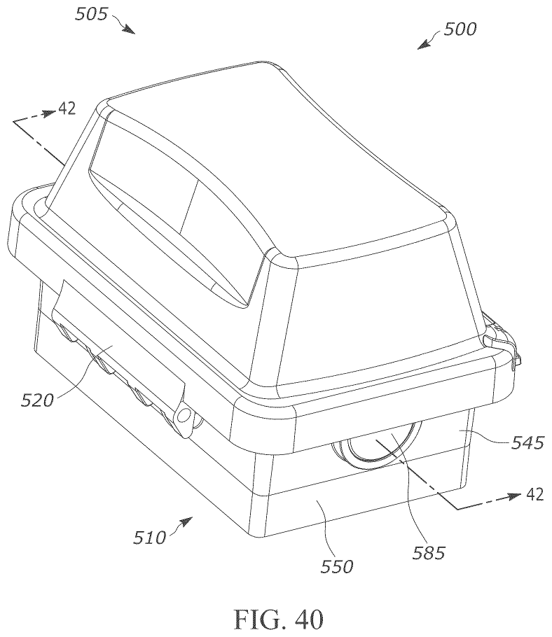

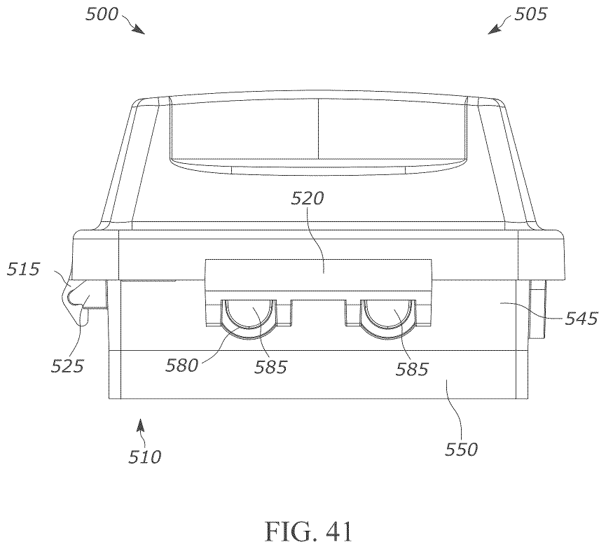

As shown in FIGS. 40 to 44, an alternate example of a cover 500 is shown. The cover 500 may be substantially similar to the cover 100 and only some similarities and differences may be described below.

The illustrated cover 500 may include a lid 505 and a base 510. The lid 505 may be movable relative to the base 510 and selectively securable to the base 510. For example, the lid 505 may be pivotable relative to the base 510, although other types of movement (e.g., translating) may be used.

In some forms, the lid 505 may include a first connecting region 515 and a second connecting region 520 disposed on a different edge of the lid 505 than the first connecting region 515. For example, the first connecting region 515 and the second connecting region 520 may be on perpendicular edges. As described in more detail below, either the first connecting region 515 or the second connecting region 520 may be used to connect the lid 505 to the base 510. In certain forms, the first and second connecting regions 515, 520 may each be a series of aligned cylindrical openings that can receive one or more pins.

In some forms, the base 510 may include a first connecting region 525 and a second connecting region 530 disposed on a different edge of the base 510 than the first connecting region 525. For example, the first connecting region 525 and the second connecting region 530 may be on perpendicular edges. In certain forms, the first and second connecting regions 525, 530 of the base 510 may be pins that are receivable within the respective openings of the connecting regions 515, 520 on the lid 505.

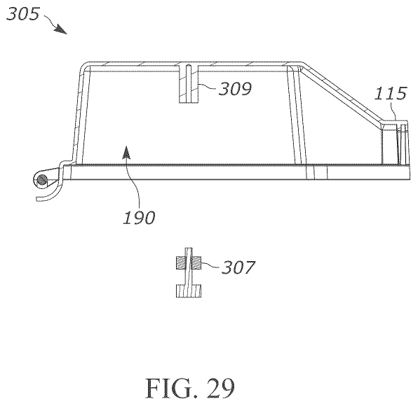

In certain forms, the connecting regions 515, 520 of the lid 505 may be on different edges than the connecting regions 525, 530 of the base 510. For example, as illustrated in FIG. 29, the lid 505 may be positioned so that the first connecting region 515 of the lid 505 is proximate to the first connecting region 525 of the base 510. However, the second connecting region 520 of the lid 505 is positioned opposite to the second connecting region 530 of the base 510. In this position, the first connecting regions 515, 525 are connected together (e.g., the pins are inserted into the openings) and the lid 505 is permitted to pivot relative to the base 510 along a first axis.

In another form, the lid 505 could be re-oriented (e.g., pivoted 180 degrees) so that the second connecting region 520 of the lid 505 is proximate to the second connecting region 530 of the base 510, and the first connecting region 515 of the lid 505 is positioned opposite to the first connecting region 525 of the base 510. In this position, the second connecting regions 520, 530 are connected together (e.g., the pins are inserted into the openings) and the lid 505 is permitted to pivot relative to the base 510 along a second axis that is substantially perpendicular to the first axis. This permits the user to select the orientation of the cover 505 relative to the base 510 so that the cover 505 can move in different directions depending on space constraints, personal preference, etc. A similar lid connection is disclosed in U.S. Pat. No. 7,439,444, which is disclosed herein by reference in its entirety.

In some forms, the lid 505 may include a latch 535 that can selectively secure the lid 505 to the base 510. For example, the latch 535 may be a cantilever member formed on the lid 505 that can selectively engage a ledge on the base 510. The ledge may extend around at least a portion of the perimeter of the base 510, or there may be multiple ledges, so that the latch 535 can engage the ledge in multiple orientations. When the lid 505 is closed (see e.g., FIGS. 40 to 4228), the latch 535 engages the ledge (e.g., via a snap fit) and limits relative movement between the lid 505 and the base 510. In this position, a substantially waterproof seal may be formed between the lid 505 and the base 510 (e.g., by a gasket disposed between the lid 505 and the base 510). To move (e.g., pivot) the lid 505 relative to the base 510, the user may move the latch 535 away from the ledge to form a clearance.

The base 510 may be similar to the base 110 and only some similarities and differences are described below. For example, the base 510 may include an internal volume 540 that may be at least partially enclosed by the lid 505 (e.g., in the closed position of FIGS. 40 to 42). The base 110 include an upper cavity 545 and an extension ring 550 that extends from the upper cavity 545. Both the upper cavity 545 and the extension ring 550 may be at least partially hollow to form the internal volume 540.

In some forms, the upper cavity 545 and the extension ring 550 may be integrally formed with one another. For example, the upper cavity 545 and the extension ring 550 may be formed during a single manufacturing process (e.g., molding), and may be a single, unitary piece. A common wall may extend between the upper cavity 545 and the extension ring 550 so that there is no gap or other possible ingress along the interface between the upper cavity 545 and the extension ring 550. The base 510 may further not require sealing between the upper cavity 545 and the extension ring 550 because they are formed as a single, unitary piece.

In certain forms, the upper cavity 545 and the extension ring 550 may be at least partially constructed from a resilient material (e.g., silicone). For example, a transition between the upper cavity 545 and the extension ring 550 may be formed from the resilient material, which may permit the upper cavity 545 to move relative to the extension ring 550 without the upper cavity 545 disconnecting from the extension ring 550. For example, a transition between the upper cavity 545 and the extension ring 550 may be formed by one or more telescopic members that may be expandable or collapsible to change the volume of the cover 500 depending on a size of an electrical device and/or a mounting space. A similar expandable cover is disclosed in U.S. Pat. No. 7,541,540, which is incorporated herein by reference in its entirety.

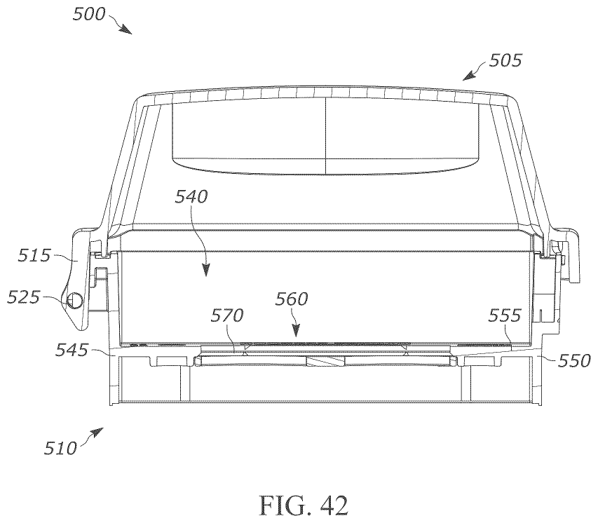

As shown in FIG. 42, a flange 555 may be formed across a portion of the internal volume 540. For example, the flange 555 may extend from the transition between the upper cavity 545 and the extension ring 550. The flange 555 may leave a central opening 560 that allows passage between the upper cavity 545 and the extension ring 550 across the internal volume 540.

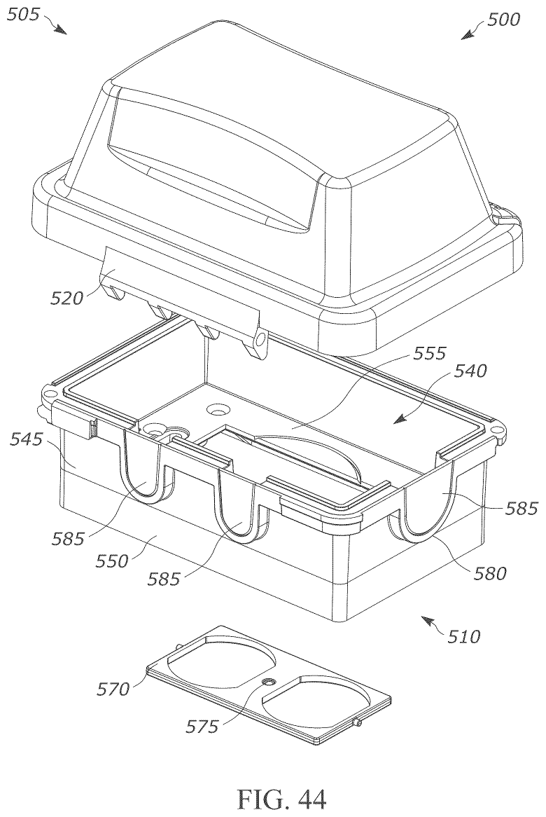

As shown in FIG. 44, the flange 555 may include one or more apertures 565, which may be formed in a variety of shapes and sizes. As described in more detail below, one or more electrical devices may be secured to the flange 555 within the internal volume using one or more of the apertures 565.

In some forms, the cover 500 may be connected to an electrical box (not shown—like electrical box 220). For example, the electrical box may connect to the extension ring 550 (e.g., with a snap fit, a press fit, a friction fit, etc.) to expand and enclose the internal volume 540. Once connected, the engagement between the electrical box and the cover 500 may form a substantially water-resistant engagement (e.g., to limit ingress of liquids into the internal volume 540).

The cover 500 may be used with a third electrical device (not shown). For example, the third electrical device may be a standard electrical outlet, a GFCI outlet, a USB outlet, etc. In the illustrated example of FIG. 44, a faceplate 570 may be used to support the third electrical device. The faceplate 570 may be similar to the faceplate 245. The illustrated faceplate 570 is a single gang faceplate 570 and may support a single switch or duplex receptacle.

In some forms, the faceplate 570 may be substantially rectangular in shape and may include an outer dimension that is like the outer dimension of the flange 555. The faceplate 570 may include at least one fastener opening 575 disposed proximate to an outer perimeter of the faceplate 570. When positioned within the internal volume 540, the fastener openings 575 may be aligned with the apertures 565. A fastener (not shown) may be inserted through an aligned fastener opening 575 and aperture 565 to secure the faceplate within the cover 500.

A second electrical device may be received through the faceplate 570 so that it is accessible within the upper cavity 545 (e.g., the plug of an electrical outlet faces into the upper cavity 545). The second electrical device may also extend toward the electrical box where it can connect to an electrical conductor. The second electrical device may be smaller than the first electrical device, but the extension ring 550 may still provide additional clearance between the second electrical device and the electrical box.

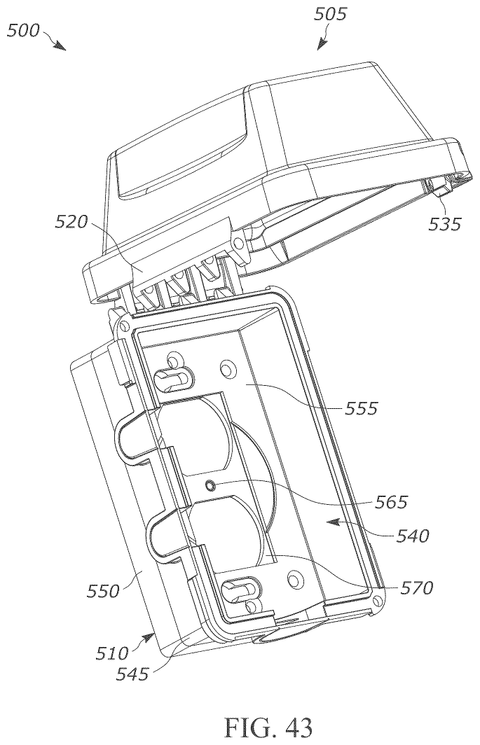

In some forms, a cord may be electrically connected to the third electrical device while the lid 505 remains in the open position (see e.g., FIG. 43). After use, the user may unplug the cord and close the lid 505 to enclose the third electrical device within the internal volume 540.

In some forms, the cover 500 may include one or more knockouts 580 which can be filled with blocking portions 585. A cord may be inserted through the space left after removing the knockout 580 so that the internal volume 540 can be accessed while the lid 505 is in the closed position. The blocking portions 585, which may be substantially similar to the blocking portions 185, may be constructed from a deformable material and may permit the cord to enter the internal volume 540 while the cover 500 remains substantially waterproof.

One of ordinary skill will appreciate that the exact dimensions and materials are not critical to the disclosure and all suitable variations should be deemed to be within the scope of the disclosure if deemed suitable for carrying out the objects of the disclosure.

One of ordinary skill in the art will also readily appreciate that it is well within the ability of the ordinarily skilled artisan to modify one or more of the constituent parts for carrying out the various examples of the disclosure. Once armed with the present specification, routine experimentation is all that is needed to determine adjustments and modifications that will carry out the present disclosure.

The above examples are for illustrative purposes and are not intended to limit the scope of the disclosure or the adaptation of the features described herein. Those skilled in the art will also appreciate that various adaptations and modifications of the above-described preferred examples can be configured without departing from the scope and spirit of the disclosure. Therefore, it is to be understood that, within the scope of the appended claims, the disclosure may be practiced other than as specifically described.

What is claimed is:

1. An in-use cover for an electrical device, the cover comprising:
a base having an internal volume, the base including:
an upper cavity, and
an extension ring coupled to the upper cavity,
wherein the upper cavity and the extension ring are integrally formed from a unitary piece;
a lid pivotably connected to the base, the lid movable between an open position that at least partially exposes the electrical device and a closed position that is configured to enclose the electrical device in the internal volume.

2. The cover of claim 1, further comprising a flange disposed within the internal volume between the upper cavity and the extension ring, wherein the electrical device is configured to be secured to the flange.

3. The cover of claim 2, wherein in the closed position, a distance between the flange and an interior surface of the cover within the internal volume is a first distance, wherein the first distance is configured to be less than a combined height of a head and electrical contacts of an electrical plug to limit disconnection of the electrical plug from the electrical device in the closed position.

4. The cover of claim 1, further comprising a first extension extending from the lid and a second extension extending from the base, wherein in the closed position, the first extension and the second extension are configured form a channel in the closed position.

5. The cover of claim 4, further comprising a blocking portion positioned within the first extension and/or the second extension and configured to limit liquid from entering the channel, wherein a shape of the blocking portion is configured to change to accommodate an electrical cord.

6. The cover of claim 1, wherein:
the base includes a first hinge portion and the lid includes a second hinge portion;
a pin is received through the first hinge portion and the second hinge portion, and configured to permit the lid to rotate relative to the base.

7. The cover of claim 1, wherein the lid includes a first connection region and a second connection region, the first connection region configured to connect to the base and permit rotation about a first axis and the second connection region configured to connect to the base and permit rotation about a second axis substantially perpendicular with respect to the first axis.

8. An electrical enclosure for housing an electrical device, the electrical enclosure comprising:
an in-use cover including:
a base having an internal volume, the base including:
an upper cavity,
an extension ring coupled to the upper cavity,
a flange disposed between within the internal volume between the upper cavity and the extension ring,
wherein the upper cavity and the extension ring are integrally formed from a unitary piece;
a lid pivotably connected to the base, the lid movable between an open position that at least partially exposes the internal volume and a closed position that is configured to enclose the internal volume;
an electrical box coupled to the extension ring and configured to expand the internal volume.

9. The electrical enclosure of claim 8, further comprising a first extension extending from the lid and a second extension extending from the base, wherein in the closed position, the first extension and the second extension are configured form a channel in the closed position.

10. The electrical enclosure of claim 9, further comprising a blocking portion positioned within the first extension and/or the second extension and configured to limit liquid from entering the channel, wherein a shape of the blocking portion is configured to change to accommodate an electrical cord.

11. The electrical enclosure of claim 8, wherein the flange extends around an entire perimeter of the base and includes a central opening configured to receive the electrical device, and wherein the flange includes at least one opening configured to receive a fastening member for securing the electrical device within the central opening.

12. The electrical enclosure of claim 8, wherein in the closed position, a distance between the flange and an interior surface of the cover within the internal volume is a first distance, wherein the first distance is configured to be less than a combined height of a head and electrical contacts of an electrical plug to limit disconnection of the electrical plug from the electrical device in the closed position.

13. The electrical enclosure of claim 8, wherein the base and the electrical box are connected together with a snap fit that is configured to create a substantially water-tight interface.

14. The electrical enclosure of claim 8, wherein:
the base includes a first hinge portion and the lid includes a second hinge portion;
a pin is received through the first hinge portion and the second hinge portion, and configured to permit the lid to rotate relative to the base;
wherein the lid is biased toward the base and is configured to automatically snap-fit with the base when it is released from an open position.

15. The cover of claim 8, wherein the lid includes a first connection region and a second connection region, the first connection region configured to connect to the base and permit rotation about a first axis and the second connection region configured to connect to the base and permit rotation about a second axis substantially perpendicular with respect to the first axis.

16. An electrical system comprising:
an in-use cover including:
a base having an internal volume, the base including:
an upper cavity,
an extension ring coupled to the upper cavity,
a flange disposed between within the internal volume between the upper cavity and the extension ring,
wherein the upper cavity and the extension ring are integrally formed from a unitary piece;
a lid pivotably connected to the base, the lid movable between an open position that at least partially exposes the internal volume and a closed position that is configured to enclose the internal volume;
an electrical box coupled to the extension ring and configured to expand the internal volume; and
an electrical device coupled to the flange and accessible within the upper cavity, the electrical device extending toward the electrical box, wherein the extension ring provides clearance between the electrical device and a surface of the electrical box.

17. The electrical system of claim 16, further comprising a faceplate configured to receive the electrical device, wherein the faceplate is directly coupled to the flange and supports the electrical device within the base.

18. The electrical system of claim 16, further comprising a first extension extending from the lid and a second extension extending from the base, wherein in the closed position, the first extension and the second extension are configured form a channel in the closed position.

19. The electrical system of claim 18, further comprising a blocking portion positioned within the first extension and/or the second extension and configured to limit liquid from entering the channel, wherein a shape of the blocking portion is configured to change to accommodate an electrical cord.

20. The electrical system of claim 18, wherein:
the base includes a first hinge portion and the lid includes a second hinge portion;
a pin is received through the first hinge portion and the second hinge portion, and configured to permit the lid to rotate relative to the base;
wherein the lid is biased toward the base and is configured to automatically snap-fit with the base when it is released from an open position.

21.-26. (canceled)
